(19) United States
(12) Patent Application Publication
(10) Pub. No.: US 2015/0160670 A1
(43) Pub. Date: Jun. 11, 2015

(54) METHODS AND SYSTEMS FOR USING DISTRIBUTED ENERGY RESOURCES IN AN ELECTRIC NETWORK

(71) Applicant: Georgia Tech Research Corporation, Atlanta, GA (US)

(72) Inventors: Athanasios Panagiotis Meliopoulos, Atlanta, GA (US); Renke Huang, Atlanta, GA (US); Fan Cai, Atlanta, GA (US); Evangelos Farantatos, Knoxville, TN (US); Robert Douglas Gill, Oakland, CA (US)

(73) Assignee: Georgia Tech Research Corporation, Atlanta, GA (US)

(21) Appl. No.: 14/100,418

(22) Filed: Dec. 9, 2013

(51) Int. Cl. G05F 1/66; G05B 15/02; G01R 21/00

(52) U.S. Cl. CPC G05F 1/66; G01R 21/00; G05B 15/02

(57) ABSTRACT

Methods and systems for using distributed energy resources in an electric network are disclosed. In one example, a system for use in controlling an electric network is described. The system includes a plurality of sensors coupled to a plurality of locations in an electric network to monitor operating conditions of the electric network at the plurality of locations. At least one state estimator is communicatively coupled to the plurality of sensors and configured to output substantially real-time estimations of a state of the electric network based, at least in part, on the monitored operating conditions. A management system is coupled to receive the substantially real-time estimations from the at least one state estimator. The management system is configured to control operation of the electric network based, at least in part, on the substantially real-time estimations to facilitate minimizing transmission losses in the electric network.

### BACKGROUND OF THE INVENTION

The embodiments described herein relate generally to electric power generation and delivery systems and, more particularly, to systems and methods for using distributed energy resources (DER) in an electric network.

Power generated by an electric utility is typically delivered to a customer via an electric network or grid that consists of transmission and distribution circuits. The electric power generation and transmission system is closely monitored and controlled by an electric grid control system that includes a large number of individual subsystems, which may also include multiple components. Typically, information is transmitted from many of the subsystems/components to the control system for use in controlling operation of the electric grid. For example, some power utilities utilize an Energy Management System or Control Center.

Known Energy Management Systems include a plurality of components and subsystems that communicate with, and may be controlled by, a central management system, typically located at the utility. The components and subsystems may be distributed at various points in the utility network to facilitate power transmission. Due at least in part to the large scale of an Energy Management System, and the quantity of individual component/subsystems that may be included, information at the management system, for use in centralized management of the generation and transmission, is generally expansive and complex.

Generally, a majority of customers (i.e., loads) are located at the distribution circuits. Power utilities desire to monitor and control the components that are distributed along the distribution circuits. For this purpose, some power utilities utilize what is referred to as a “smart grid.”

At least some known smart grids include a plurality of components and subsystems that communicate with, and may be controlled by, a central management system, typically located at the utility. The components and subsystems may be distributed at various points in the utility distribution network to facilitate power distribution to customers. Due at least in part to the large scale of a smart grid, and the quantity of individual component/subsystems that may be included in the smart grid, information at the management system, for use in centralized management of the smart grid, is generally expansive and complex.

Electric power losses across distribution feeders in an electric network, is a concern for distribution systems engineers. Between about three percent and about eight percent of power transmitted on distribution feeders is lost. The electric power losses include ohmic losses, losses from reactive power flow, and losses due to harmonic currents resulting from nonlinear loads of the system. Presently, various voltage/Var control schemes are sometimes used to reduce transmission losses. In at least one known scheme, Var compensation is implemented by the use of the capacitor banks that are placed on critical buses of an electric network system to supply reactive power to support and attempt to optimize the voltage profile of the system. Real time control actions can be implemented up to some extent through switched capacitor banks. However, such capacitor banks, including switched capacitor banks, are placed only at discrete points of the electric network and inject discrete levels of reactive power. Moreover, the control of switched capacitor banks is commonly based on information local to the particular switched capacitor bank.

### BRIEF DESCRIPTION OF THE INVENTION

One aspect of the present application is a system for use in controlling an electric network. The system includes a plurality of sensors coupled to a plurality of locations in an electric network to monitor operating conditions of the electric network at the plurality of locations. At least one state estimator is communicatively coupled to the plurality of sensors and configured to output substantially real-time estimations of a state of the electric network based, at least in part, on the monitored operating conditions. A management system is coupled to receive the substantially real-time estimations from the at least one state estimator. The management system is configured to control operation of the electric network based, at least in part, on the substantially real-time estimations to facilitate minimizing transmission losses in the electric network.

Another aspect of the present disclosure is a system for use in use in controlling an electric network. The system includes a processor and a non-transitory computer readable medium coupled to the processor. The non-transitory computer readable medium contains instructions that, when executed by the processor, cause the processor to receive at least one network state estimation from a state estimator that receives sensor data from at least one sensor coupled to the electric network, determine one or more actions affecting an operation of the electric network to facilitate minimizing power losses in the electric network based at least in part on the network state estimation, and control operation of the electric network based, at least in part, on the determined one or more actions.

In another aspect of the present application, a method for use in use in controlling an electric network is described. The method includes receiving sensor data from at least one sensor coupled to the electric network, estimating at least one network state based at least in part on the received sensor data, determining one or more actions affecting an operation of the electric network to facilitate minimizing power losses in the electric network based at least in part on the estimated network state, and controlling operation of the electric network based, at least in part, on the determined one or more actions.

### BRIEF DESCRIPTION OF THE DRAWINGS

FIG. 1 is a block diagram of an exemplary electric power generation and delivery system.

FIG. 2 is a block diagram of an exemplary management system that may be used to manage the electric power generation and delivery system shown in FIG. 1.

FIG. 3 is a block diagram of a portion of the electric power generation and delivery system shown in FIG. 1 including a functional block diagram of the management system shown in FIG. 2.

FIG. 4 is a block diagram illustrating the inputs, outputs and optimization algorithms of an optimizer for use in the portion of the electric power generation and delivery system shown in FIG. 3.

FIG. 5 is a flow diagram of an example method for use in controlling an electric network.

### DETAILED DESCRIPTION OF THE INVENTION

The following detailed description illustrates exemplary embodiments of the invention by way of example and not by way of limitation. It is contemplated that the invention has general application to analytical and methodical embodiments of managing operation and maintenance of widely geographically diverse power assets in industrial, commercial, and residential applications.

Exemplary embodiments of the methods and systems described herein relate to electric power generation and delivery systems and, more particularly, to systems and methods for using distributed energy resources (DER) in an electric network. The methods and systems described herein may be implemented using computer programming or engineering techniques including computer software, firmware, hardware or any combination or subset thereof, wherein an exemplary technical effect may include at least one of: a) receiving sensor data from at least one sensor coupled to an electric network; b) estimating at least one network state based at least in part on received sensor data; c) determining one or more actions affecting an operation of an electric network to facilitate minimizing power losses in the electric network based at least in part on an estimated network state; and d) controlling operation of an electric network based, at least in part, on a determined one or more actions affecting an operation of the electric network.

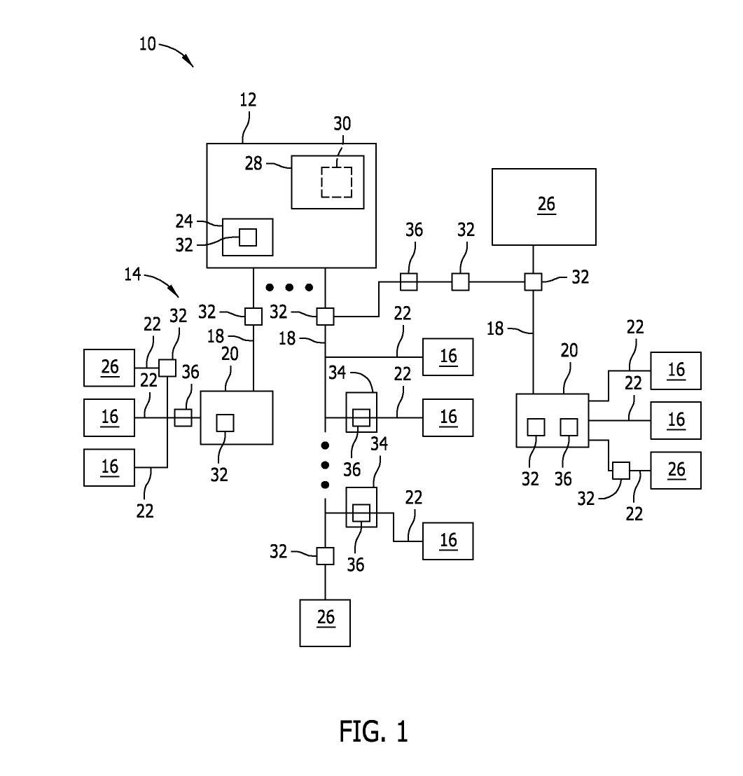

FIG. 1 is a block diagram of an exemplary electric power generation and delivery system 10. In the exemplary embodiment, electric power generation and delivery system 10 includes an electric utility 12, electric grid 14, and a plurality of customer or energy user locations 16. Moreover, electricity is delivered from electric utility 12 to customer or energy user locations 16 via electric grid 14. More specifically, electric grid 14 includes a plurality of transmission lines 18, a plurality of electric substations 20, and a plurality of distribution lines 22 that enable distribution of electricity. Although transmission lines 18 and distribution lines 22 are illustrated as single lines, each transmission line 18 and distribution line 22 may include one or more lines, each carrying a single phase, two phases, or three phases of power.

Moreover, in the exemplary embodiment, electric utility 12 includes an electric power generation system 24 that supplies electrical power to electric grid 14. Electric power generation system 24 may include a generator driven by, for example, a gas turbine engine, a hydroelectric turbine, a wind turbine, one or more solar panels, and/or another suitable generation system. In the exemplary embodiment, system 10 includes multiple distributed energy resources 26. Distributed energy resources 26 may include a generator driven by, for example, a gas turbine engine, a hydroelectric turbine, a wind turbine, one or more solar panels, one or more batteries or banks of batteries, and/or another suitable power generation system. Distributed energy resources 26 may belong to (e.g. be owned by or be part of) electric utility 12, may belong to a different electric utility, or may belong to a customer of the utility. Although four distributed energy sources 26 are shown in the exemplary embodiment, electric power generation and delivery system 10 may include any number of distributed energy sources 26 distributed throughout grid 14.

Electric utility 12 also includes a distribution control center substation 28 that facilitates control of energy production and/or delivery. Distribution control center substation 28 is illustrated as being included within electric utility 12, however, distribution control center substation 28 may be external to electric utility 12 (e.g., remotely located, etc.) and in communication with electric utility 12, or it may be located in one of the utility substations 20. Moreover, distribution control center substation 28 may be in communication with distributed energy resources 26, whether located internal or external to distributed energy resources 26.

Distribution control center substation 28 includes a management system 30 that provides operator control for managing power delivered from electric power generation system 24 and/or distributed into electric grid 14. Management system 30 may control distribution to electrical substations 20, to customer or energy user locations 16, and/or other suitable points within electric grid 14. Management system 30 may be usable to detect operating conditions in the electric grid 14, alter a configuration of grid 14, and/or other operations associated with electric grid 14 and/or electric power generation system 24. Specifically, in the exemplary embodiment, management system 30 is coupled to a plurality of switchable assets 32 distributed throughout system 10.

In one example, management system 30 may be employed to rapidly respond to outage/fault conditions to reconfigure to electric grid 14, via one or more switchable assets 32 (sometimes referred to herein as switches 32), in an effort to limit potential safety issues, to control power distribution, and/or to limit damage to/from electric grid 14. In another example, to enable the installation of equipment or the replacement of existing equipment, a switch plan may be provided to safely de-energize a section of conductor prior to performing the work. Management system 30 may determine a switch plan and create a planned outage order associated with the switch plan. Management system 30 may also be configured to simulate the switch plan in order to ensure accuracy, safety, and effectiveness of the switch plan. The availability of work crews and tools necessary to perform a desired maintenance/repair may also be coordinated by management system 30. Specifically, management system 30 may be useable by a dispatcher or a network operator to dispatch work crews and tools to appropriate locations, and/or to coordinate switch plans to minimize impact on operation of electric grid 14.

In at least one embodiment, management system 30 may include a user interface that enables a user, such as such as dispatcher, a network operator, utility engineer, a systems engineer, a transmission engineer, etc., to manage electric grid 14.

In the exemplary embodiment, system 10 includes an advanced metering infrastructure (AMI) subsystem that includes AMI meters 34. AMI meters 34 measure and/or detect an amount of electricity received and/or provided to one or more loads (such as energy user locations 16, etc.) coupled to AMI meters 34. Meters 34 transmit data, such as electricity measurement data, to, and/or receive data from, other devices or systems (including management system 30) within system 10 and/or the AMI subsystem. System 10 may include any suitable number of AMI meters 34. In the exemplary embodiment, AMI meters 34 communicate with other devices and systems via wireless communication over a communication network, such as, e.g., the Internet, a cellular network, etc. In other embodiments, AMI meters 34 may communicate with other devices and systems via wired and/or wireless communication. Moreover, AMI meters 34 may communicate directly or indirectly with other devices and systems.

Sensors 36 are distributed throughout electric grid 14. Sensors 36 may be included within AMI meters 34 and/or may be separate, stand-alone sensors 36. Each sensor 36 monitors one or more parameters of power transmitted through grid 14 at that sensors location. The parameters can include, but are not limited to, a voltage magnitude, a current magnitude, phase of a voltage, phase of a current, etc. In the exemplary embodiment, sensors 36 are communicatively coupled to management system 30. Accordingly, management system 30 may receive current state data from throughout grid 14 from sensors 36 distributed throughout grid 14. Sensors 36 may be coupled to management system 30 directly or indirectly. Moreover, sensors 36 may be coupled to management system by a wired connection and/or a wireless connection.

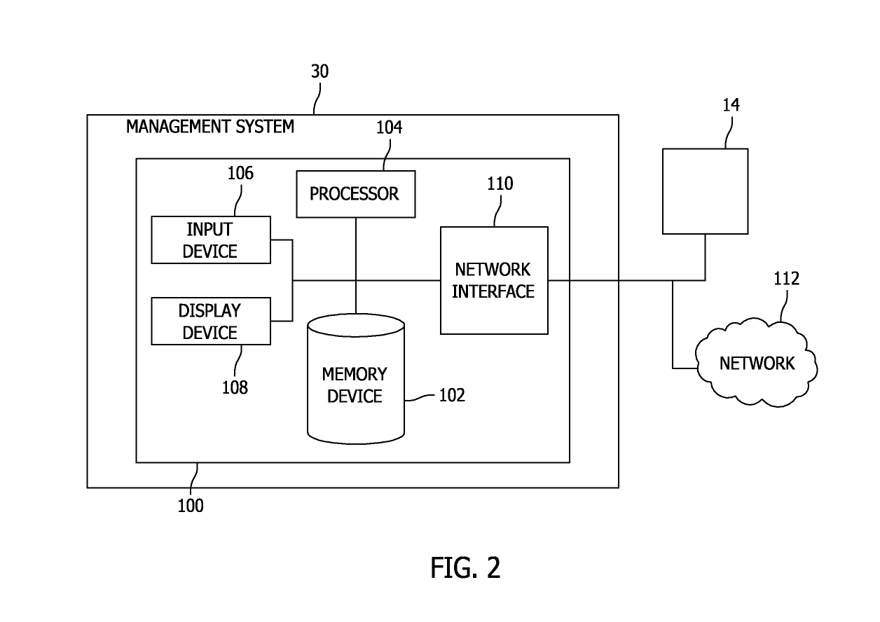

FIG. 2 is an exemplary block diagram of management system 30. In the exemplary embodiment, management system 30 includes a computing assembly 100. Computing assembly 100 may include a personal computer, a workstation, a server, a network computer, a mobile computer, a portable digital assistant (PDA), a smart phone, or other suitable device. As illustrated, computing assembly 100 includes a display device 108, a memory device 102 and a processor 104 in communication with display device 108 and memory device 102. Display device 108 may include, without limitation, a cathode ray tube (CRT) display, a liquid crystal display (LCD), an organic light emitting diode (OLED) display, or other suitable device for use in presenting information to a user (not shown).

Memory device 102 is any suitable device that may be used for storing and/or retrieving information, such as executable instructions and/or data. Memory device 102 may include any computer readable medium, such as hard disk storage, optical drive/disk storage, removable disk storage, flash memory, random access memory (RAM), etc. While memory device 102 is illustrated as a single element in FIG. 2, it should be appreciated that memory device 102 may include one or multiple separate memory devices, located together or remote from one another.

Processor 104 may include one or more processing units (e.g., in a multi-core configuration). The term processor, as used herein, refers to central processing units, microprocessors, microcontrollers, reduced instruction set circuits (RISC), application specific integrated circuits (ASIC), logic circuits, and any other circuit or processor capable of executing instructions. Processor 104 may be programmed to perform alone or in combination any of the processes, methods or functions described herein.

Computing assembly 100 includes an input device 106 for receiving input from user. Input device 106 may include, without limitation, a keyboard, a pointing device, a mouse, a stylus, a touch sensitive panel (e.g., a touch pad or a touch screen), a gyroscope, an accelerometer, a position detector, and/or an audio input device. A single component, such as a touch screen, may function as both display device 108 and input device 106. Further, the particular example embodiment of FIG. 2, computing assembly 100 includes a network interface 110. Network interface 110 may provide communication between computing assembly 100 and electric grid 14 and/or one or more public networks 112, such as Internet, Intranet, a local area network (LAN), a cellular network, a wide area network (WAN), etc.

As described above, grid 14 may be configured and/or reconfigured using management system 30, for example by use of switchable assets 32. Moreover, distributed energy resources 26 may be controlled and/or switched in and/or out of grid 14 using management system 30. By controlling distributed energy resources 26, management system 30 may actively reduce distribution losses in grid 12.

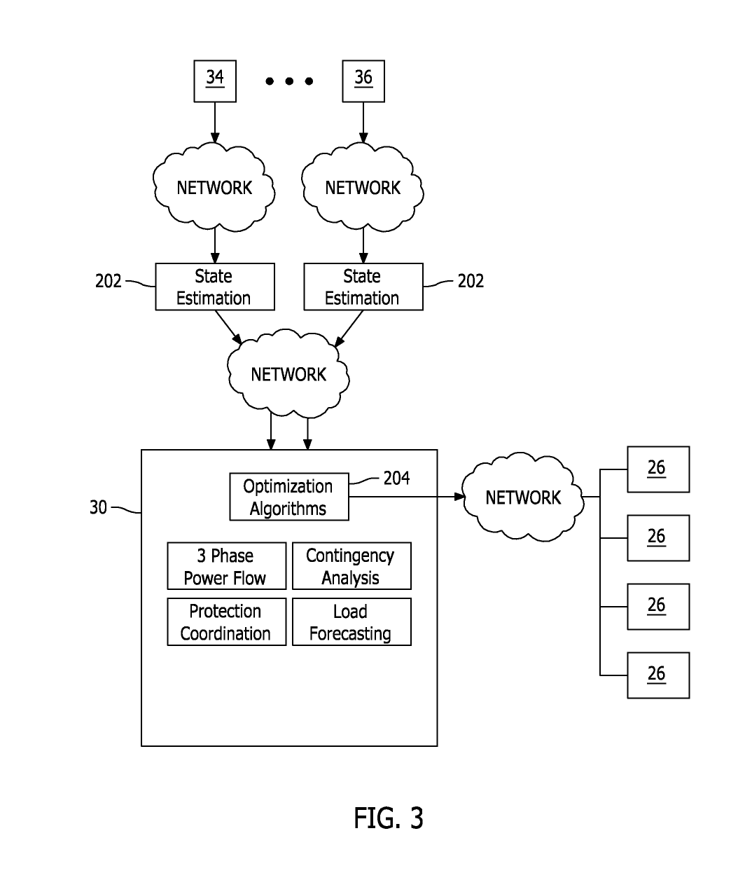

FIG. 3 is a portion of electric power generation and delivery system 10 including a functional block diagram of management system 30. AMI meters 34 and sensors 36 are communicatively coupled to state estimators 202. In the exemplary embodiment, each AMI meter 34 and each sensor 36 is coupled to a different state estimator 202. In other embodiments, more than one AMI meter 34 and/or sensor 36 may be coupled to a single state estimator 202. Moreover, in the exemplary embodiment, each state estimator 202 is communicatively coupled to management system 30.

State estimators 202 receive data from a plurality of AMI meters 34 and/or sensors 36. The data includes the characteristics, e.g., voltage, current, phase, etc., monitored by the AMI meters 34 and/or sensors 36. Based at least in part on the received data, each state estimator 202 estimates the present state of three phases of power for a portion of system 10 covered by the AMI meter 34 and/or sensor 36 from which it received the data. In the exemplary embodiment, state estimators 202 model asymmetries and imbalances in system 10. The resulting state estimation is provided to management system 30 to provide management system 30 with substantially real time data of the present state of system 10, and more particularly grid 14. State estimator 202 uses a multiplicity of inputs from the AMI meters 34 and/or sensors 36. Each input is related via a mathematical model to the present state of the system defined with the voltage magnitude and phase at each node of the portion of the system 10 for which it applies. In the exemplary embodiment, state estimator 202 receives more input data as compared to the present system state (i.e., redundant input data). A best estimate of the present system state is mathematically computed for the portion of system 10 from which state estimator 202 receives data.

In the exemplary system, management system 30 includes an optimizer 204 that generates signals for use in controlling one or more element (e.g., switches 32, distributed energy resources 26, etc.) of grid 14. More specifically, optimizer 204 includes one or more optimization algorithms that receive the state estimations from state estimators 202. The optimization algorithms facilitate optimizing operation of grid 14 to achieve one or more objective. In the exemplary embodiment, the optimization algorithms attempt to minimize transmission losses in grid 14 through coordinated volt/Var control. More specifically, the optimization algorithms attempt to optimally integrate and/or operate distributed energy resources 26 in grid 14, balance the current across all phases of power distributed through grid 14, and to increase the power factor of power distributed through grid 14.

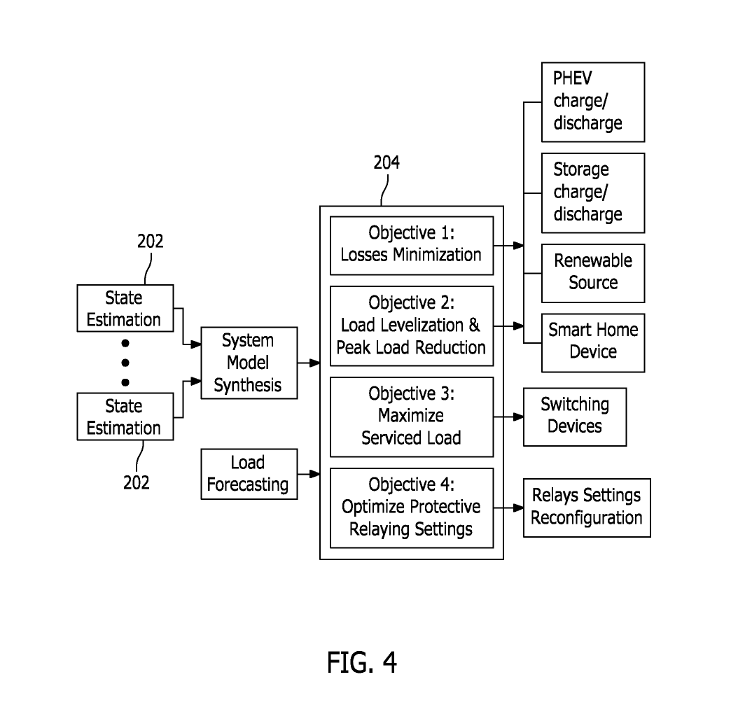

FIG. 4 is a block diagram illustrating the inputs, outputs and optimization algorithms of optimizer 204. In the exemplary embodiment, the optimization algorithm of optimizer 204 includes selectable objectives for optimal economic operation of the grid 14 or reliability improvement of the grid 14. During normal operating conditions, it is generally desired that the grid 14 operate in an optimal economic manner, which is achieved by minimization of the transmission losses and/or load levelization and peak load reduction. In addition to optimal economic operation, it is generally desired that grid 14 be reliable and secure. During abnormal conditions, after the occurrence of a fault for example, reliability improvement can be achieved by optimal grid 14 reconfiguration in order to isolate the fault to a relatively small area and restore power to as many customers as possible. In this case the optimization algorithm defines the status of the switchable assets 32 such that the minimum number of customers is affected by the specific fault. Under normal operating conditions or in case of an expected stressed condition of grid 14 (e.g. heavy loading or predicted extreme weather conditions etc.), optimizer 204 can be set to reconfigure the settings of protective relaying devices (protection coordination) such that a false trip is avoided. Independently of the objective function(s), the real time model of grid 14 that is synthesized given the real time model of each portion of the system 10 as computed by each state estimator 202, is an input of the optimizer 204. Load forecast data are useful in instances in which the objective is set to be load levelization and such data is input to optimizer 204. The output signals of optimizer 204 are control signals sent to customer and/or energy user locations 16, including but not limited to charging/discharging of a pluggable hybrid electric vehicle (PHEV) or a storage device, power output settings of customer or utility owned renewable sources (e.g. solar panels or wind turbines), operation of “smart” home devices, and other controllable energy resources, 26.

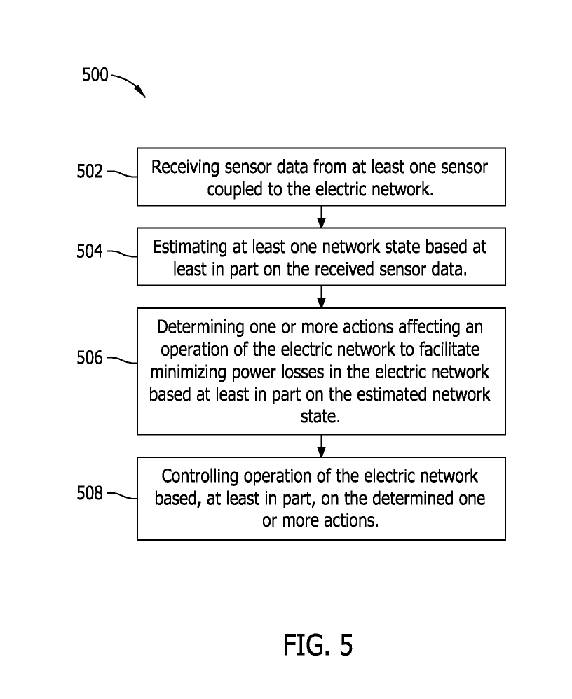

FIG. 5 is a flow diagram of an example method 500 for use in controlling an electric network, such as electric power generation and delivery system 10. Sensor data is received 502 from at least one sensor coupled to the electric network. At least one network state is estimated 504 based at least in part on the received sensor data. One or more actions affecting an operation of the electric network to facilitate minimizing power losses in the electric network is determined 506 based at least in part on the estimated network state. In one example embodiment, the one or more actions available for selection include connecting and/or disconnecting one or more switchable capacitor banks from the electric network, connecting and/or disconnecting one or more batteries to the electric network, connecting and/or disconnecting one or more distributed generators to the electric network. In some embodiments, the one or more actions available for selection include, additionally or alternatively, controlling operation of one or more distributed generators connected to the electric network, and controlling operation of one or more inverters connected to the electric network. In some embodiments, determining 506 one or more actions available for selection includes, additionally or alternatively determining a configuration of one or more switches interconnecting section of the electric network to reconfigure the electric network. In other embodiments, determining 506 one or more actions available for selection includes, additionally or alternatively, determining one or more actions to facilitate minimizing power losses in the electric network by one or more of balancing currents in the electric network and improving a power factor in the electric network. Operation of the electric network is controlled 508 based, at least in part, on the determined one or more actions.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A system for use in controlling an electric network, said system comprising:
a plurality of sensors coupled to a plurality of locations in an electric network to monitor operating conditions of the electric network at the plurality of locations;
at least one state estimator communicatively coupled to said plurality of sensors, said at least one state estimator configured to output substantially real-time estimations of a state of the electric network based, at least in part, on the monitored operating conditions; and
a management system coupled to receive the substantially real-time estimations from said at least one state estimator, said management system configured to control operation of the electric network based, at least in part, on the substantially real-time estimations to facilitate minimizing transmission losses in the electric network.

2. A system in accordance with claim 1, wherein each sensor of said plurality of sensors is configured to monitor at least one of an electric current, a voltage, a transformer tap, and a status of a circuit breaker.

3. A system in accordance with claim 1, wherein at least one sensor of said plurality of sensors is coupled in wireless communication with said at least one state estimator.

4. A system in accordance with claim 1, wherein said management system comprises an optimizer configured to determine one or more actions affecting an operation of the electric network to achieve one or more objectives based at least in part on the substantially real-time estimations from the at least one state estimator, and wherein said management system is configured to control operation of the electric network based, at least in part, on the one or more actions determined by said optimizer.

5. A system in accordance with claim 4, wherein the one or more objectives comprises minimizing transmission losses in the electric network.

6. A system in accordance with claim 5, wherein said optimizer is configured to determine one or more actions that will substantially minimize losses by substantially balance phase loading in the electric network.

7. A system in accordance with claim 6, wherein the one or more actions comprise at least one of controlling distributed resources, controlling inverter interfaced resources, and opening or closing switches in the electric network.

8. A system in accordance with claim 5, wherein said optimizer is configured to determine one or more actions that will substantially minimize losses by controlling the power factor in the electric network.

9. A system in accordance with claim 8, wherein the one or more actions comprise at least one of controlling distributed energy resources in the electric network and controlling switchable capacitors in the electric network.

10. A system in accordance with claim 5, wherein said optimizer is configured to determine one or more actions that will substantially minimize losses by a combination of balancing phase loading in the electrical network and controlling the power factor in the electric network.

11. A system in accordance with claim 5, further comprising a communication system communicatively coupled to a plurality of devices in the electric network, and wherein said management system is configured to control operation of the plurality of devices via said communication system.

12. A system for use in controlling an electric network, said system comprising:
a processor; and
a non-transitory computer readable medium coupled with said processor and containing instructions that, when executed by said processor, cause said processor to:
receive at least one network state estimation from a state estimator that receives sensor data from at least one sensor coupled to the electric network;
to determine one or more actions affecting an operation of the electric network to facilitate minimizing power losses in the electric network based at least in part on the network state estimation; and
control operation of the electric network based, at least in part, on the determined one or more actions.

13. A system in accordance with claim 12, wherein said non-transitory computer readable medium coupled with said processor contains instructions that, when executed by said processor, cause said processor to determine one or more actions that will substantially minimize losses by substantially balance phase loading in the electric network, wherein the one or more actions comprise at least one of controlling distributed resources, controlling inverter interfaced resources, and opening or closing switches in the electric network.

14. A system in accordance with claim 12, wherein said non-transitory computer readable medium coupled with said processor contains instructions that, when executed by said processor, cause said processor to determine one or more actions that will substantially minimize losses by controlling the power factor in the electric network, wherein the one or more actions comprise at least one of controlling distributed energy resources in the electric network and controlling switchable capacitors in the electric network.

15. A system in accordance with claim 12, wherein said non-transitory computer readable medium coupled with said processor contains instructions that, when executed by said processor, cause said processor to determine one or more actions that will substantially minimize losses by a combination of balancing phase loading in the electrical network and controlling the power factor in the electric network.

16. A method for use in use in controlling an electric network, said method comprising:
receiving sensor data from at least one sensor coupled to the electric network;
estimating at least one network state based at least in part on the received sensor data;
determining one or more actions affecting an operation of the electric network to facilitate minimizing power losses in the electric network based at least in part on the estimated network state; and
controlling operation of the electric network based, at least in part, on the determined one or more actions.

17. A method in accordance with claim 16, wherein said determining one or more actions affecting operation of the electric network comprises determining one or more actions selected from connecting one or more switchable capacitor banks to the electric network, connecting one or more batteries to the electric network, connecting one or more distributed generators to the electric network, disconnecting one or more switchable capacitor banks from the electric network, disconnecting one or more batteries from the electric network, disconnecting one or more distributed generators from the electric network.

18. A method in accordance with claim 16, wherein said determining one or more actions affecting operation of the electric network comprises determining one or more actions selected from controlling operation of one or more distributed generators connected to the electric network and controlling operation of one or more inverters connected to the electric network.

19. A method in accordance with claim 16, wherein said determining one or more actions affecting operation of the electric network comprises determining a configuration of one or more switches interconnecting sections of the electric network to reconfigure the electric network.

20. A method in accordance with claim 16, wherein said determining one or more actions affecting operation of the electric network comprises determining one or more actions to facilitate minimizing power losses in the electric network by one or more of balancing currents in the electric network and improving a power factor in the electric network.
